(19) United States
(12) Patent Application Publication
(10) Pub. No.: US 2025/0366168 A1
(43) Pub. Date: Nov. 27, 2025

(54) CAPACITOR CONTAINING METAL NITRIDE BARRIER LAYER AND METHOD OF MAKING THEREOF

(71) Applicant: SANDISK TECHNOLOGIES LLC, ADDISON, TX (US)

(72) Inventor: Keita KUMAMOTO, Yokkaichi (JP)

(21) Appl. No.: 18/672,531

(22) Filed: May 23, 2024

(51) Int. Cl. H01L 27/06; H01L 29/51

(52) U.S. Cl. CPC H10D 84/811; H10D 1/692; H10D 64/693

(57) ABSTRACT

A semiconductor structure includes a field effect transistor and a capacitor located on common. The field effect transistor is located on a first portion of the common substrate, and contains a gate dielectric including a first portion of a first dielectric material, and a gate electrode including, from bottom to top, a doped semiconductor gate electrode comprising a first portion of a gate semiconductor material, a first gate metal layer, and a second gate metal layer. The capacitor is located on second portion of the common substrate, and contains a middle electrode including a second portion of the gate semiconductor material, an upper node dielectric, and an upper electrode including, from bottom to top, a doped semiconductor capacitor electrode layer, a first electrode metallic nitride layer, a first electrode metal layer, and a second electrode metal layer.

### FIELD

The present disclosure relates generally to the field of semiconductor devices, and particularly to a capacitor containing a metal nitride barrier layer and methods for manufacturing the same.

### BACKGROUND

A capacitor may include a capacitor dielectric layer, such as a silicon oxide layer, between opposing electrically conductive electrodes.

### SUMMARY

According to an aspect of the present disclosure, a semiconductor structure includes a field effect transistor and a capacitor located on common. The field effect transistor is located on a first portion of the common substrate, and contains a gate dielectric including a first portion of a first dielectric material, and a gate electrode including, from bottom to top, a doped semiconductor gate electrode comprising a first portion of a gate semiconductor material, a first gate metal layer, and a second gate metal layer. The capacitor is located on second portion of the common substrate, and contains a middle electrode including a second portion of the gate semiconductor material, an upper node dielectric, and an upper electrode including, from bottom to top, a doped semiconductor capacitor electrode layer, a first electrode metallic nitride layer, a first electrode metal layer, and a second electrode metal layer.

According to another aspect of the present disclosure, a method of forming a semiconductor structure comprises forming a gate dielectric material layer, a first doped semiconductor material layer, and a capacitor material layer stack over a substrate, wherein the capacitor material layer stack comprises, from bottom to top, an upper node dielectric material layer, a second doped semiconductor material layer, and a first electrode metallic nitride material layer; removing a first portion of the capacitor material layer stack from a transistor region while retaining at least a part of a second portion of the capacitor material layer stack in a capacitor region; forming an upper layer stack including a first metal layer and a second metal layer over the second portion of the capacitor material layer stack in the capacitor region and over the first doped semiconductor material layer in the transistor region; and patterning the upper layer stack, the second portion of the capacitor material layer stack and first doped semiconductor material layer to form a capacitor in the capacitor region and to form a gate electrode in the transistor region.

### BRIEF DESCRIPTION OF THE DRAWINGS

FIG. 1 is a vertical cross-sectional view of an exemplary structure after formation of a lower electrode according to an embodiment of the present disclosure.

FIG. 2 is a vertical cross-sectional view of the exemplary structure after formation of a gate dielectric material layer and a first doped semiconductor material layer according to an embodiment of the present disclosure.

FIG. 3 is a vertical cross-sectional view of the exemplary structure after formation of shallow trench isolation structures according to an embodiment of the present disclosure.

FIG. 4 is a vertical cross-sectional view of the exemplary structure after formation of a capacitor material layer stack including an upper node dielectric material layer, a second doped semiconductor material layer, and a first electrode metallic nitride material layer according to an embodiment of the present disclosure.

FIG. 5 is a vertical cross-sectional view of the exemplary structure after patterning a stack of a first electrode metallic nitride layer, a doped semiconductor capacitor electrode layer, and an upper node dielectric according to an embodiment of the present disclosure.

FIG. 6 is a vertical cross-sectional view of the exemplary structure after formation of an upper layer stack including a first metal layer, a second electrode metallic nitride material layer, and a second metal layer according to an embodiment of the present disclosure.

FIG. 7 is a vertical cross-sectional view of the exemplary structure after patterning the upper layer stack, and the first doped semiconductor material layer according to an embodiment of the present disclosure.

FIG. 8 is a vertical cross-sectional view of the exemplary structure after formation of a source extension region and a drain extension region according to an embodiment of the present disclosure.

FIG. 9 is a vertical cross-sectional view of the exemplary structure after formation of a middle electrode contact structure according to an embodiment of the present disclosure.

FIG. 10 is a vertical cross-sectional view of the exemplary structure after formation of a dielectric gate spacer, additional dielectric spacers, a deep source region, and a deep drain region according to an embodiment of the present disclosure.

FIG. 11 is a vertical cross-sectional view of the exemplary structure after formation of a contact-level dielectric layer and contact via cavities according to an embodiment of the present disclosure.

FIG. 12 is a vertical cross-sectional view of the exemplary structure after formation of metal-semiconductor alloy regions according to an embodiment of the present disclosure.

FIG. 13 is a vertical cross-sectional view of the exemplary structure after formation of various contact via structures according to an embodiment of the present disclosure.

### DETAILED DESCRIPTION

Embodiments of the present disclosure are directed to a capacitor containing a metal nitride barrier layer between a metal and heavily doped semiconductor electrode layers and methods for manufacturing the same. The metal nitride barrier layer prevents or reduces time-dependent dielectric breakdown (TDDB) of the capacitor due to diffusion of metal atoms from the metal electrode into the semiconductor electrode layer and/or into the capacitor dielectric layer.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element.

As used herein, a “layer” refers to a material portion including a region having a thickness. A layer may extend over the entirety of an underlying or overlying structure, or may have an extent less than the extent of an underlying or overlying structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which flow of charge carriers (e.g., electrons or holes) is affected by an applied electrical field. A “gate electrode” refers to an electrically conductive electrode applies an electric field that controls charge carrier flow in the channel region by. A “source region” refers to a doped semiconductor region that supplies charge carriers (e.g., electrons or holes) that flow through the channel region. A “drain region” refers to a doped semiconductor region that receives the charge carriers supplied by the source region and that flow through the channel region. A “source/drain region” may be a source region or a drain region. An “active region” collectively refers to a source region, a drain region, and a channel region of a field effect transistor. A “source extension region” refers to a doped semiconductor region that is a portion of a source region and having a lesser dopant concentration than the rest of the source region. A “drain extension region” refers to a doped semiconductor region that is a portion of a drain region and having a lesser dopant concentration than the rest of the drain region. An “active region extension” refers to a source extension region or a drain extension region.

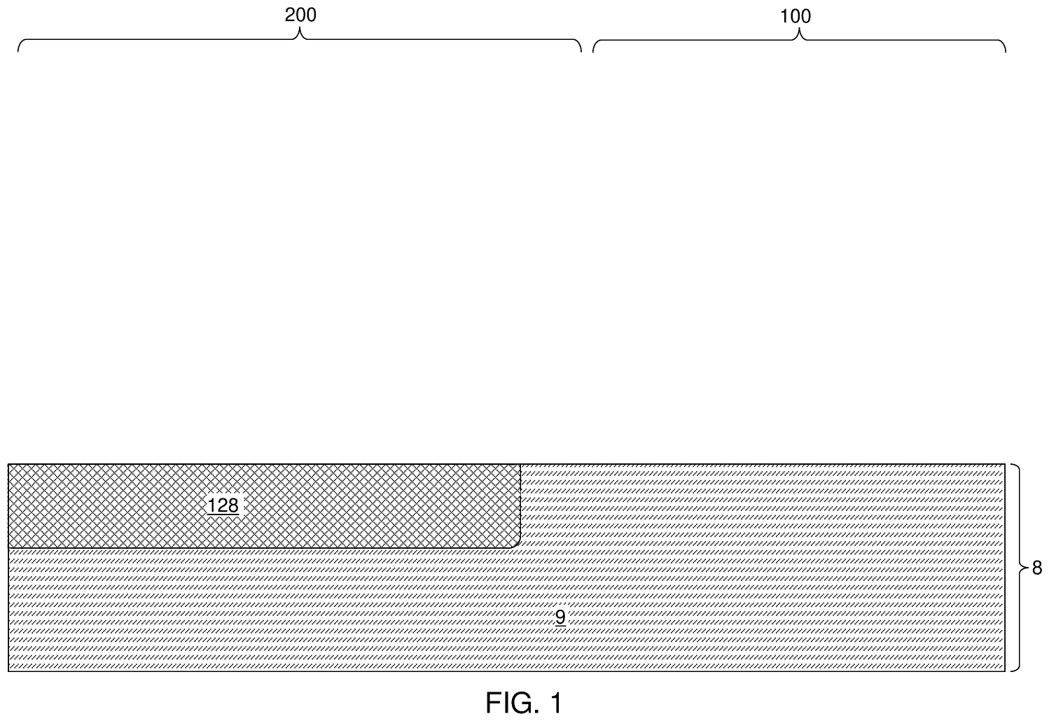

Referring to FIG. 1, an exemplary structure according to an embodiment of the present disclosure is illustrated. The exemplary structure includes a semiconductor substrate 8. As used herein, a “semiconductor substrate” refers to a substrate that includes at least one semiconductor material portion, i.e., at least one portion of a semiconductor material. The semiconductor substrate 8 includes a substrate semiconductor material layer 9 at least at a top portion thereof. The semiconductor substrate 8 may optionally include at least one additional material layer at a bottom portion thereof. In one embodiment, the semiconductor substrate 8 can be a bulk semiconductor substrate consisting of a semiconductor material (e.g., single crystal silicon wafer), or can be a semiconductor-on-insulator (SOI) substrate including a buried insulator layer (such as a silicon oxide layer) underlying the semiconductor (e.g., silicon) material portion, and a handle substrate underlying the buried insulator layer.

The substrate semiconductor material layer 9 may include a lightly doped semiconductor material portion, on which at least one field effect transistor can be subsequently formed. In one embodiment, the entirety of the semiconductor substrate 8 may be the substrate semiconductor material layer 9. In another embodiment, the substrate semiconductor material layer 9 may comprise an upper portion of the semiconductor substrate 8, such as a doped silicon wafer. The substrate semiconductor material layer 9 may include a lightly doped semiconductor material including electrical dopants of a first conductivity type at an atomic concentration in a range from 1.0×10¹⁴/cm³ to 1.0×10¹⁸/cm³, such as from 1.0×10¹⁵/cm³ to 1.0×10¹⁷/cm³, although lesser and greater atomic concentrations can also be employed. The first conductivity type may be p-type or n-type.

The semiconductor material of the substrate semiconductor material layer 9 can be an elemental semiconductor material (such as silicon) or an alloy of at least two elemental semiconductor materials (such as a silicon-germanium alloy), or can be a compound semiconductor material (such as a III-V compound semiconductor material or a II-VI compound semiconductor material), or can be an organic semiconductor material. The thickness of the substrate semiconductor material layer 9 can be in a range from 0.5 mm to 2 mm in case the semiconductor substrate 8 is a bulk semiconductor substrate. In case the semiconductor substrate 8 is a semiconductor-on-insulator substrate, the thickness of the substrate semiconductor material layer 9 may be in a range from 100 nm to 1,000 nm, although lesser and greater thicknesses can also be employed.

A masked ion implantation process can be performed to implant electrical dopants into a surface portion of the substrate semiconductor material layer 9 to form a doped well in the transistor region 100 and/or in the capacitor region 200. In one embodiment, the doped well comprises a p-doped well. In one embodiment, an inversion layer or accumulation layer of the p-doped well functions as a lower electrode 128 of a three-terminal, multi-dielectric capacitor. In this embodiment, the lower electrode 128 is formed in the capacitor region 200, as shown in FIG. 1. Optionally, an additional masked ion implantation process may be performed to form at least one doped well (not illustrated) in a surface portion of the transistor region 100. For example, a double well structure or a triple well structure may be provided within an upper portion of the transistor region 100. According to an aspect of the present disclosure, the device regions comprise transistor regions 100 in which a respective field effect transistor is to be subsequently formed and capacitor regions 200 in which a respective capacitor is to be subsequently formed. A transistor region 100 and a capacitor region 200 are illustrated in FIG. 1.

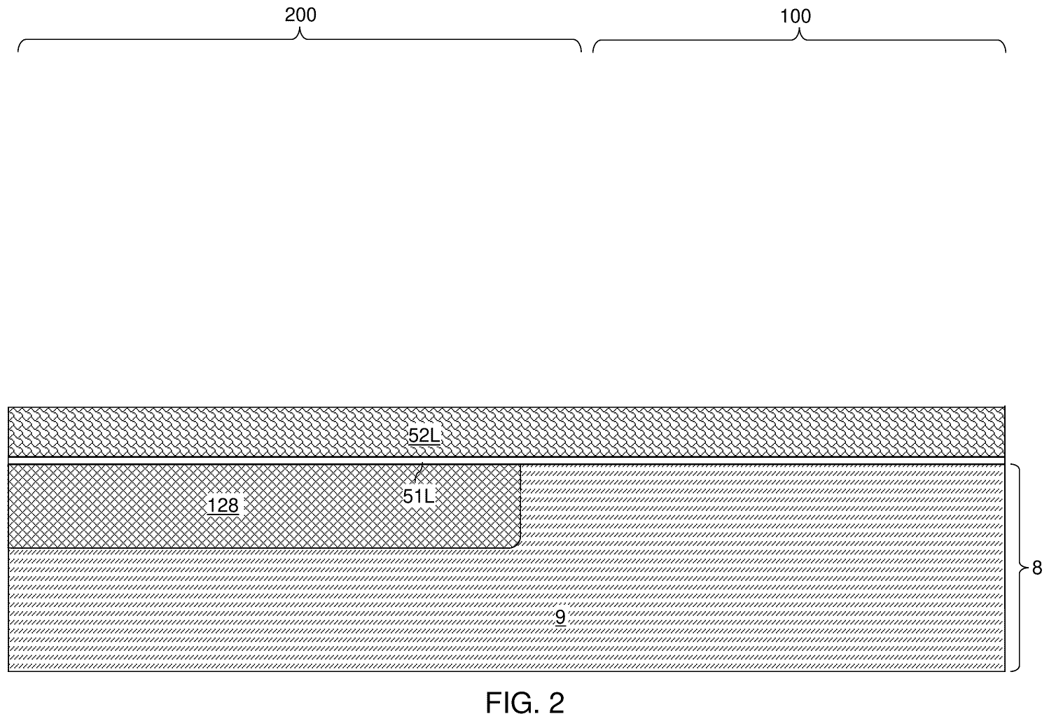

Referring to FIG. 2, a gate dielectric material layer 51L and a first doped semiconductor material layer 52L can be sequentially formed over the top surface of the semiconductor substrate 8. The gate dielectric material layer 51L may comprise any gate dielectric material known in the art, such as silicon oxide or silicon oxynitride. The thickness of the gate dielectric material layer 51L may be in a range from 2 nm to 12 nm, such as from 5 nm to 10 nm, although lesser and greater thicknesses may also be employed.

The first doped semiconductor material layer 52L comprises a doped semiconductor material, which may be any type of doped semiconductor material in the art. The first doped semiconductor material layer 52L may be formed as an undoped semiconductor material layer, and may be subsequently doped by an ion implantation process either globally or locally (employing a masked ion implantation process). Alternatively, the first doped semiconductor material layer 52L may be formed as a heavily doped semiconductor material layer by a semiconductor deposition process employing in-situ doping. Generally, each portion of the first doped semiconductor material layer 52L located in the transistor region 100 and the capacitor region 200 may be doped with the same or different conductivity type (e.g., p-type or n-type) electrical dopants to function as a middle electrode of a capacitor. For example, the first doped semiconductor material layer 52L may comprise a heavily doped polysilicon or amorphous silicon doped with n-type (e.g., phosphorus) dopants at a concentration of 1×10¹⁹/cm³ to 5×10²¹/cm³. The thickness of the first doped semiconductor material layer 52L may be in a range from 30 nm to 100 nm, such as from 50 nm to 70 nm, although lesser and greater thicknesses may also be employed.

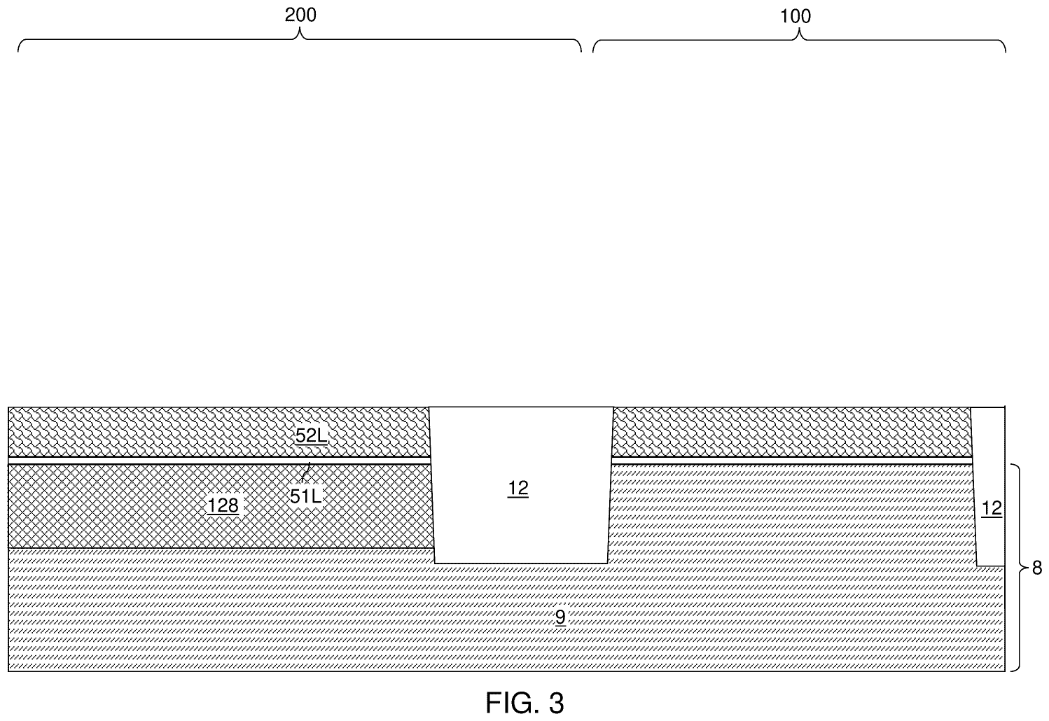

Referring to FIG. 3, shallow trench isolation structures 12 can be formed through the first doped semiconductor material layer 52L and the gate dielectric material layer 51L and in the upper portion of the substrate semiconductor material layer 9. The shallow trench isolation structures 12 may laterally surround remaining surface portions of the substrate semiconductor material layer 9 in each device region (100, 200) in which a respective device is to be subsequently formed. In one embodiment, each patterned portion of the first doped semiconductor material layer 52L and the gate dielectric material layer 51L in the transistor region 100 and the capacitor region 200 may be laterally surrounded by a respective shallow trench isolation structure 12.

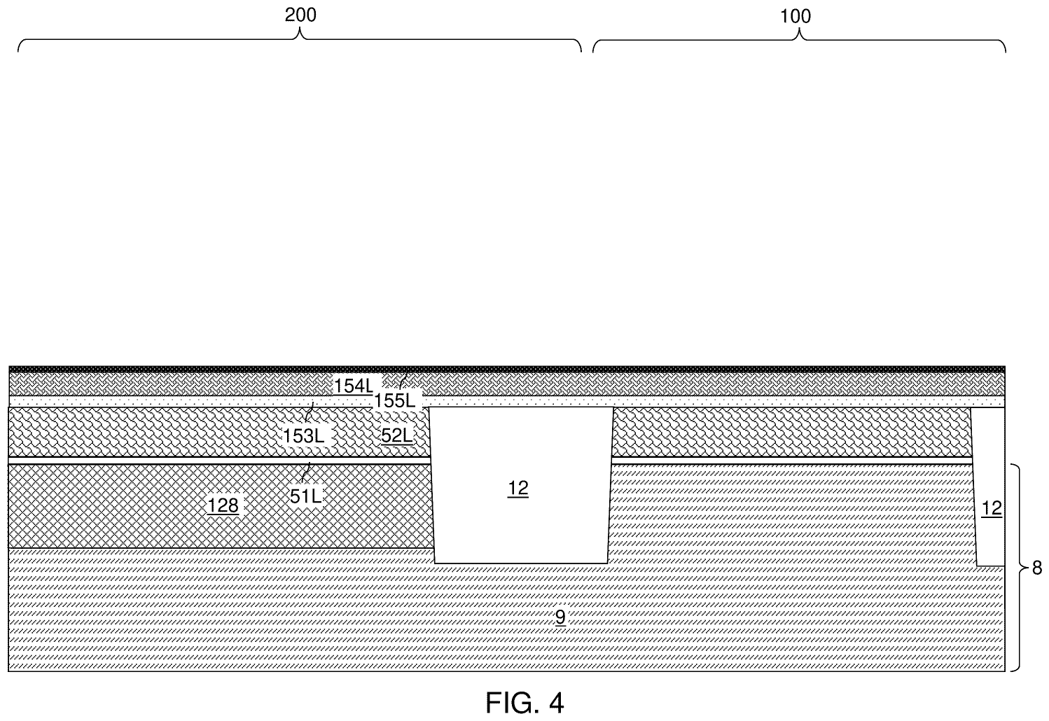

Referring to FIG. 4, a capacitor material layer stack (153L, 154L, 155L) can be formed over the first doped semiconductor material layer 52L and the shallow trench isolation structures 12. The capacitor material layer stack (153L, 154L, 155L) includes, from bottom to top, the upper node dielectric material layer (i.e., the upper capacitor dielectric layer) 153L, a second doped semiconductor material layer 154L, and a first electrode metallic nitride material layer 155L.

The upper node dielectric material layer 153L may comprise any capacitor dielectric material known in the art, such as silicon oxide, silicon oxynitride or silicon nitride. For example, the thickness of the upper node dielectric material layer 153L may be in a range from 5 nm to 15 nm, such as from 7 nm to 12 nm, although lesser and greater thicknesses may also be employed.

The second doped semiconductor material layer 154L comprises a doped semiconductor material, which may be any type of doped semiconductor material in the art. The second doped semiconductor material layer 154L may be formed as an undoped semiconductor material layer, and may be subsequently doped by an ion implantation process. Alternatively, the second doped semiconductor material layer 154L may be formed as a heavily doped semiconductor material layer by a semiconductor deposition process employing in-situ doping. Generally, the second doped semiconductor material layer 154L may be heavily doped with suitable electrical dopants to provide high electrical conductivity to function as portion of an upper electrode material of the capacitor. For example, the second doped semiconductor material layer 154L may comprise a heavily doped polysilicon or amorphous silicon doped with n-type (e.g., phosphorus) dopants at a concentration of 1×10¹⁹/cm³ to 5×10²¹/cm³. The thickness of the second doped semiconductor material layer 154L may be in a range from 10 nm to 50 nm, such as from 15 nm to 30 nm, although lesser and greater thicknesses may also be employed. In one embodiment, second doped semiconductor material layer 154L may be thinner than the first doped semiconductor material layer 152L.

The first electrode metallic nitride material layer 155L comprises a first metallic nitride material that functions as a diffusion barrier and is configured to suppress diffusion of metal atoms therethrough. The first electrode metallic nitride material layer 155L consists essentially of an electrically conductive metal nitride material that functions as a diffusion barrier material. For example, the first electrode metallic nitride material layer 155L may consist essentially of titanium nitride, tantalum nitride, tungsten nitride, or molybdenum nitride. In one embodiment, the first electrode metallic nitride material layer 155L consists essentially of titanium nitride. The thickness of the first electrode metallic nitride material layer 155L is selected at a minimum thickness that is effective for blocking diffusion of metal atoms, such as Ti atoms. For example, the thickness of the first electrode metallic nitride material layer 155L may be in a range from 2 nm to 30 nm, such as from 3 nm to 10 nm, although lesser and greater thicknesses may also be employed.

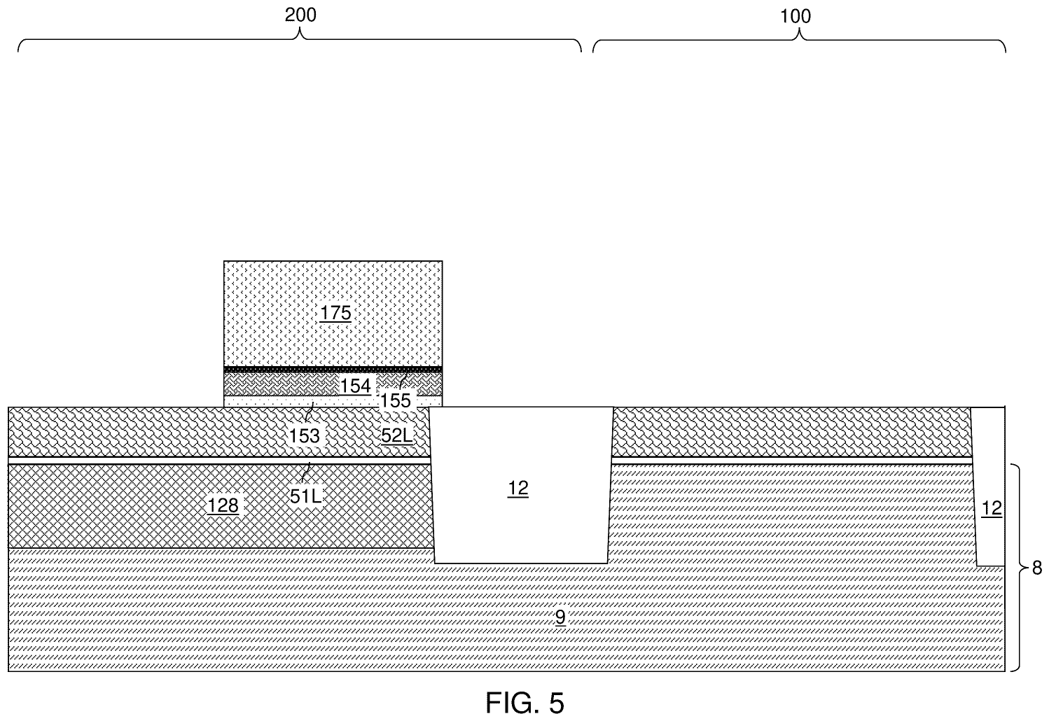

Referring to FIG. 5, a first photoresist layer 175 can be applied over the capacitor material layer stack (153L, 154L, 155L), and can be lithographically patterned to cover an area within the capacitor region 200 without covering the area of the transistor region 100. For example, the patterned first photoresist layer 175 can cover part of the capacitor region 200 adjacent to the shallow trench isolation structures 12. The first photoresist layer 175 covers a portion of the first doped semiconductor material layer 52L and a neighboring portion of the shallow trench isolation structures 12. An etch process can be performed to etch the materials of the capacitor material layer stack (153L, 154L, 155L) from the transistor region 100 while preventing removal of the covered portions of the capacitor material layer stack (153L, 154L, 155L) from the capacitor region 200. The etch process may comprise a series of etch steps for sequentially etching the materials of the capacitor material layer stack (153L, 154L, 155L) from top to bottom. The terminal etch step of the etch process may be selectively etch the material of the upper node dielectric material layer 153L selective to the material of the first doped semiconductor material layer 52L. The series of etch steps may comprise at least one anisotropic etch process (such as at least one reactive ion etch process) and/or at least one isotropic etch process (such as at least one wet etch process). The first photoresist layer 175 can be subsequently removed, for example, by ashing.

A patterned portion of the first electrode metallic nitride material layer 155L comprises a first electrode metallic nitride layer 155. A patterned portion of the second doped semiconductor material layer 154L comprises a doped semiconductor capacitor electrode layer 154. A patterned portion of the upper node dielectric material layer 153L comprises an upper node dielectric 153. Sidewalls of the first electrode metallic nitride layer 155, the doped semiconductor capacitor electrode layer 154, and the upper node dielectric 153 may be vertically coincident among one another. As used herein, two or more surfaces are vertically coincident if the two or more surfaces are located within a same vertical plane and if the two or more surfaces overlie or underlie one another. In one embodiment, a sidewall of the first electrode metallic nitride layer 155, a sidewall of the doped semiconductor capacitor electrode layer 154, and a sidewall of the upper node dielectric 153 can be formed entirely within the area of a shallow trench isolation structure 12 in a top view. In another embodiment, a sidewall of the first electrode metallic nitride layer 155, a sidewall of the doped semiconductor capacitor electrode layer 154, and a sidewall of the upper node dielectric 153 can extend over the shallow trench isolation structure 12, but is located within the outer sidewall boundary of the shallow trench isolation structure 12 in the top view.

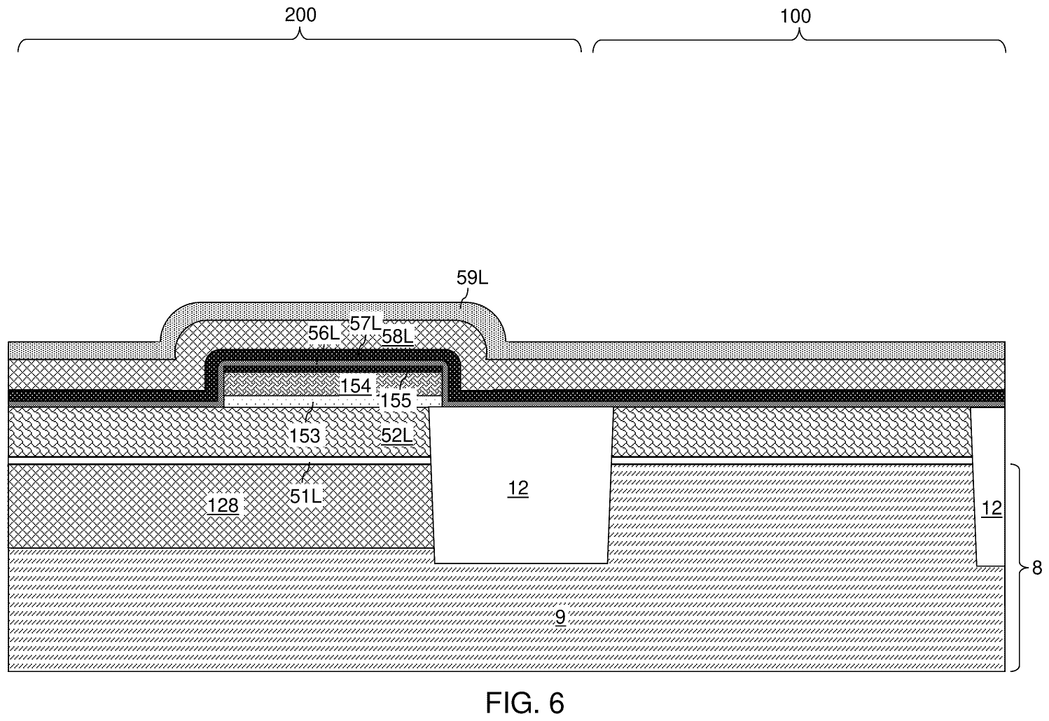

Referring to FIG. 6, an upper layer stack (56L, 57L, 58L, 59L) including a first metal layer 56L, a second electrode metallic nitride material layer 57L, a second metal layer 58L, and an optional capping dielectric layer 59L can be deposited over the remaining portions of the capacitor material layer stack (153L, 154L, 155L) in the capacitor region 200 and over the first doped semiconductor material layer 52L in the transistor region 100. A portion of the upper layer stack (56L, 57L, 58L, 59L) overlying a stack of a first electrode metallic nitride layer 155, a doped semiconductor capacitor electrode layer 154, and an upper node dielectric 153 may form a bump structure that protrudes above a horizontal plane including a portion of a top surface of the capping dielectric layer 59L located in the transistor region 100.

The first metal layer 56L is deposited directly on a top surface of the first portion of the first doped semiconductor material layer 52L in the transistor region 100, and directly on a top surface of the first electrode metallic nitride material layer 155L in the capacitor region 200. The first metal layer 56L comprises and/or consists essentially of a barrier metal. In one embodiment, the first metal layer 56L comprises and/or consists essentially of a transition metal such as titanium, tantalum, tungsten, etc. In one embodiment, the first metal layer 56L comprises and/or consists essentially of titanium. The thickness of the horizontally-extending portions of the first metal layer 56L may be in a range from 1 nm to 3 nm, such as from 1.2 nm to 2 nm, although lesser and greater thicknesses may also be employed.

The second electrode metallic nitride material layer 57L comprises a second metallic nitride material that can function as a diffusion barrier layer and suppress diffusion of metal atoms from the second metal layer 58L. The second metallic nitride material may be the same as or may be different from the first metallic nitride material of the first electrode metallic nitride material layer 155L. For example, the second electrode metallic nitride material layer 57L may consist essentially of titanium nitride, tantalum nitride, tungsten nitride, or molybdenum nitride. In one embodiment, the second electrode metallic nitride material layer 57L consists essentially of titanium nitride. The thickness of the second electrode metallic nitride material layer 57L may be greater than the thickness of the first electrode metallic nitride material layer 155L. For example, the thickness of the second electrode metallic nitride material layer 57L may be in a range from 4 nm to 15 nm, such as from 6 nm to 10 nm, although lesser and greater thicknesses may also be employed.

The second metal layer 58L comprises a transition metal having high electrical conductivity. In one embodiment, the second metal layer 58L may comprise a refractory metal such as tungsten, molybdenum, or tantalum. The thickness of the second metal layer 58L may be in a range from 15 nm to 60 nm, such as from 20 nm to 50 nm, although lesser and greater thicknesses may also be employed.

The optional capping dielectric layer 59L comprises a diffusion barrier dielectric material such as silicon oxide, silicon oxynitride and/or silicon nitride. For example, the optional capping dielectric layer 59L may comprise a lower silicon oxide sublayer and an upper silicon nitride sublayer. The thickness of the capping dielectric layer 59L may be in a range from 50 nm to 120 nm, such as from 70 nm to 100 nm, although lesser and greater thicknesses may also be employed.

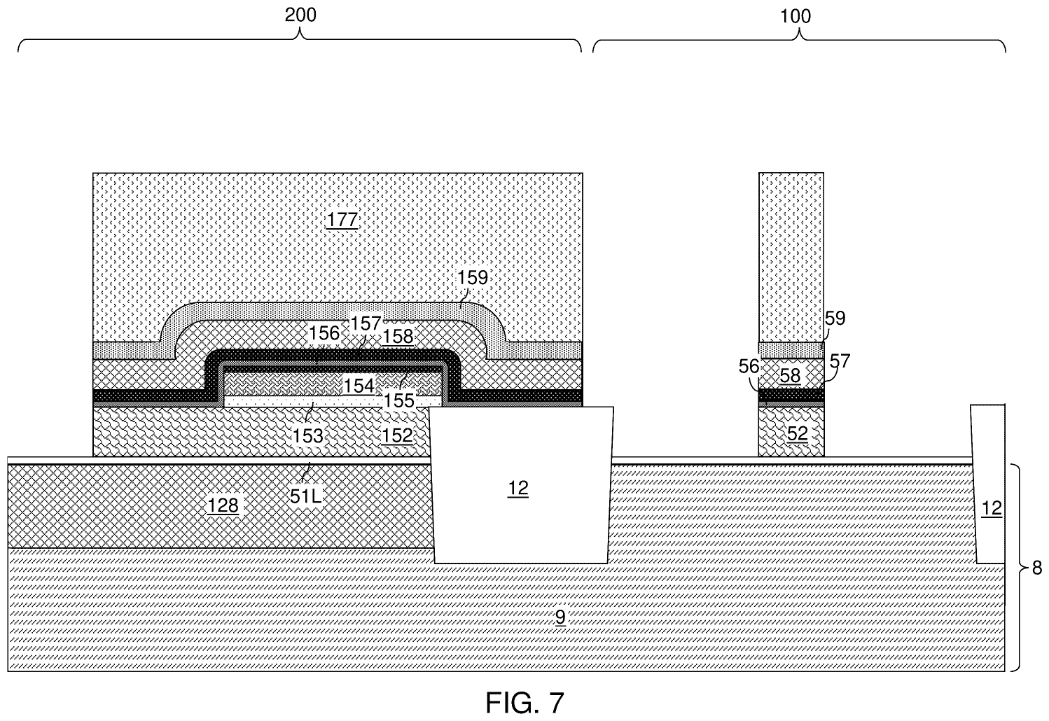

Referring to FIG. 7, a second photoresist layer 177 can be formed over the capping dielectric layer 59L, and can be lithographically patterned to cover an area in which a capacitor is to be subsequently formed in the capacitor region 200, and to cover an area in which a gate electrode is to be subsequently formed in the transistor region 100. An anisotropic etch process can be performed to transfer the pattern in the second photoresist layer 177 through the upper layer stack (56L, 57L, 58L, 59L), and the first doped semiconductor material layer 52L. The anisotropic etch process stops on the gate dielectric material layer 51L.

A first patterned portion of the capping dielectric layer 59L in the transistor region 100 comprises a gate capping dielectric 59, a first patterned portion of the second metal layer 58L in the transistor region 100 comprises a second gate metal layer 58, a first patterned portion of the second electrode metallic nitride material layer 57L in the transistor region 100 comprises a gate metallic nitride layer 57, a first patterned portion of the first metal layer 56L in the transistor region 100 comprises a first gate metal layer 56, and a first patterned portion of the first doped semiconductor material layer 52L in the transistor region 100 comprises a doped semiconductor gate electrode 52.

A contiguous combination of patterned portions of the upper layer stack (56L, 57L, 58L, 59L) and the doped semiconductor gate electrode 52 in the transistor region 100 comprises a gate electrode (52, 56, 57, 58) of a transistor. Thus, the gate electrode (52, 56, 57, 58) comprises a doped semiconductor gate electrode 52, a first gate metal layer 56, a gate metallic nitride layer 57, and a second gate metal layer 58. In one embodiment, a top surface of the doped semiconductor gate electrode 52 contacts a bottom surface of the first gate metal layer 56. The gate metallic nitride layer 57 is located between and contacts the first gate metal layer 56 and the second gate metal layer 58.

A second patterned portion of the capping dielectric layer 59L in the capacitor region 200 comprises a capacitor capping dielectric 159, a second patterned portion of the second metal layer 58L in the capacitor region 200 comprises a second electrode metal layer 158, a second patterned portion of the second electrode metallic nitride material layer 57L in the capacitor region 200 comprises a second electrode metallic nitride layer 157, a second patterned portion of the first metal layer 56L in the capacitor region 200 comprises a first electrode metal layer 156, and a second patterned portion of the first doped semiconductor material layer 52L in capacitor region 200 comprises a middle electrode 152.

The first electrode metallic nitride layer 155 may have a lesser lateral extent than the first electrode metal layer 156 and the second electrode metal layer 158. The middle electrode 152 may have a greater lateral extent as the upper node dielectric 153. The first gate metal layer 56 and the first electrode metal layer 156 have the same material composition and have a same thickness. In one embodiment, the first gate metal layer 56 and the first electrode metal layer 156 consist essentially of titanium. The second gate metal layer 58 and the second electrode metal layer 158 have a same material composition (e.g., tungsten) and have a same thickness. The gate metallic nitride layer 57 and the second electrode metallic nitride layer 157 have a same material composition (e.g., TiN) and a same thickness. The second photoresist layer 177 can be subsequently removed, for example, by ashing.

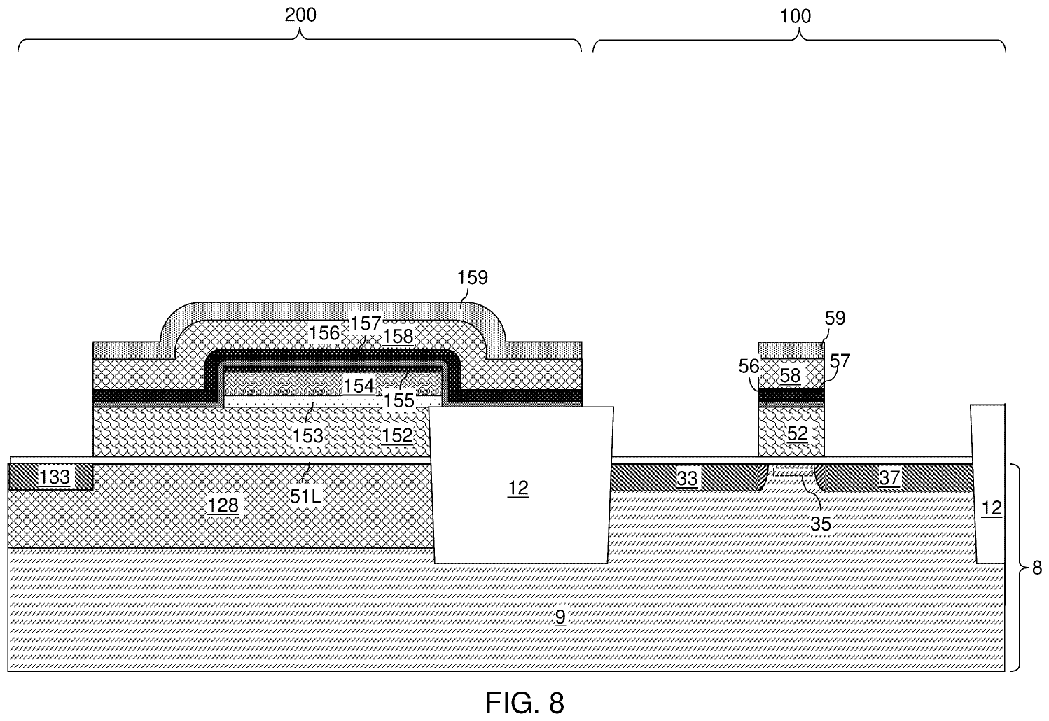

Referring to FIG. 8, a masked or unmasked ion implantation process can be performed to form a source extension region 33 and a drain extension region 37 in the transistor region 100. The gate electrode (52, 56, 57, 58) and the gate capping dielectric 59 may be employed as self-aligned etch mask structures during the ion implantation process. A channel region 35 is formed between the source extension region 33 and the drain extension region 37. A lightly doped contact region 133 is also formed in the exposed portion of the doped well portion of the lower electrode 128 in the capacitor region 200.

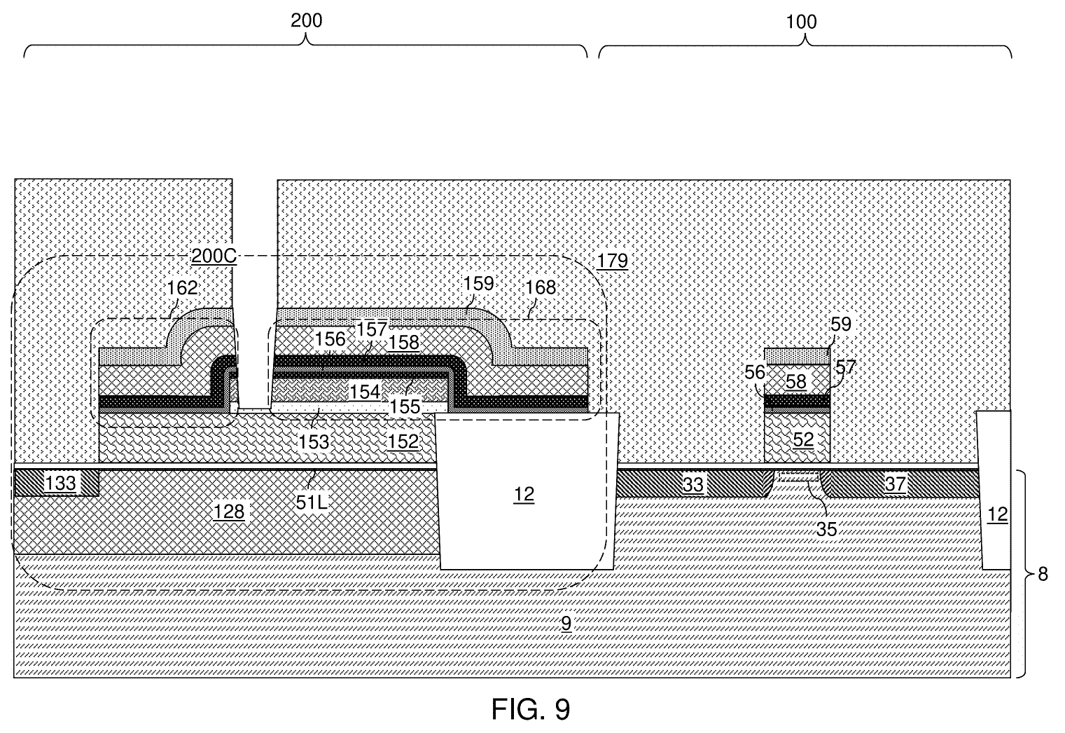

Referring to FIG. 9, a third photoresist layer 179 can be applied over the gate capping dielectric 59 and the capacitor capping dielectric 159, and can be lithographically patterned to form an opening that laterally extends along vertical interfaces between the second electrode metal layer 158 and the doped semiconductor capacitor electrode layer 154. The opening in the third photoresist layer 179 can be formed within a peripheral area of the doped semiconductor capacitor electrode layer 154 that overlies the middle electrode 152, and may extend into an adjacent portion of the shallow trench isolation structures 12. Generally, a portion of the second electrode metal layer 158 that does not underlie the opening in the third photoresist layer continuously extends from above a shallow trench isolation structure 12 in contact with the middle electrode 152 to an area that overlies a predominant fraction (i.e., more than 50%) of the area of the doped semiconductor capacitor electrode layer 154.

An anisotropic etch process can be performed to transfer the pattern of the opening in the third photoresist layer 179 through the capacitor capping dielectric 159, the second electrode metal layer 158, the second electrode metallic nitride layer 157, the first electrode metal layer 156, the first electrode metallic nitride layer 155, and the doped semiconductor capacitor electrode layer 154, and into the upper node dielectric 153. The capacitor capping dielectric 159, the second electrode metal layer 158, the second electrode metallic nitride layer 157, the first electrode metal layer 156, the first electrode metallic nitride layer 155, and the doped semiconductor capacitor electrode layer 154 is divided into two contiguous portions that are laterally spaced from each other by a trench that underlies the opening in the third photoresist layer 179. A contiguous combination of patterned portions of the second electrode metal layer 158, the second electrode metallic nitride layer 157, the first electrode metal layer 156, the first electrode metallic nitride layer 155, and the doped semiconductor capacitor electrode layer 154 that includes a predominant fraction of the material of the doped semiconductor capacitor electrode layer 154 as provided after the processing steps of FIG. 8 constitutes an upper electrode 168 of a capacitor. Another contiguous combination of patterned portions of the second electrode metal layer 158, the second electrode metallic nitride layer 157, the first electrode metal layer 156, the first electrode metallic nitride layer 155, and the doped semiconductor capacitor electrode layer 154 that does not include, or includes a minor fraction of, the material of the doped semiconductor capacitor electrode layer 154 as provided after the processing steps of FIG. 8 constitutes a middle electrode contact structure 162 of the capacitor.

A segment of a top surface of the lower electrode 128 can be physically exposed. In one embodiment, the middle electrode 152 has a greater lateral extent than the upper electrode 168. In one embodiment, a first segment of a top surface of the upper node dielectric 153 contacts a bottom surface of the first electrode metallic nitride layer 155. In one embodiment, the middle electrode 152 has a greater lateral extent than the first electrode metallic nitride layer 155. In one embodiment, the doped semiconductor gate electrode 52 and the middle electrode 152 have a same height and a same material composition (e.g., heavily n-type doped polysilicon). The third photoresist layer 179 can be subsequently removed, for example, by ashing.

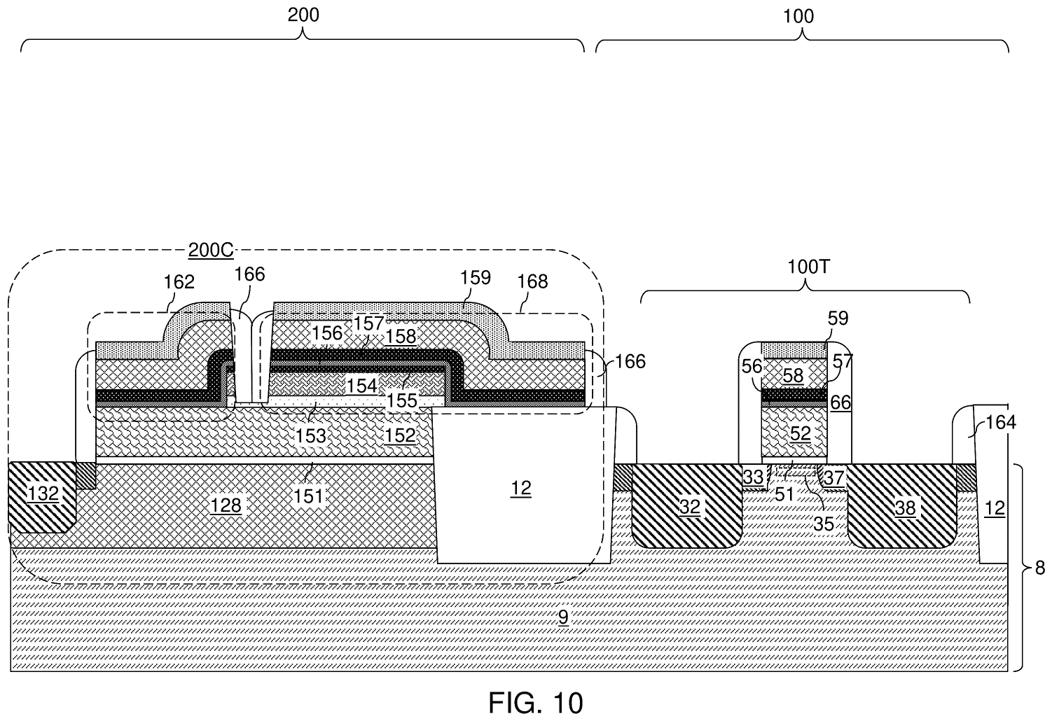

Referring to FIG. 10, at least one dielectric spacer material layer (such as silicon oxide and/or silicon nitride) can be conformally deposited and anisotropically etched to form various dielectric spacers (66, 166, 164). A dielectric gate spacer 66 is formed around the gate electrode (52, 56, 57, 58). A dielectric capacitor spacer 166 is formed around the capacitor capping dielectrics 159, the upper electrode 168, the middle electrode contact structure 162, the upper node dielectric 153 and the middle electrode 152. The gate dielectric material layer 51L is also patterned during the step of anisotropically etching the dielectric spacer material layer to form a gate dielectric 51 between the substrate and the gate electrode in the transistor region 100, and to form a lower node dielectric 151 between the substrate and the middle electrode 152 in the capacitor region 200. Additional dielectric spacers 164 can be formed around additional structures such as sidewalls of the shallow trench isolation structures 164. The dielectric gate spacer 66, the dielectric capacitor spacer 166, and the additional dielectric spacers 164 comprise a same dielectric material.

A combination of the middle electrode 152, the upper node dielectric 153, the upper electrode 168, the lower node dielectric 151, and the lower electrode 128 comprises a capacitor 200C. Thus, the capacitor 200C includes at least the middle electrode 152, the upper electrode 168, and the upper node dielectric 153 located between the middle electrode 152, the upper electrode 168. The upper electrode 168 includes, from bottom to top, a doped semiconductor capacitor electrode layer 154, a first electrode metallic nitride layer 155, a first electrode metal layer 156, a second electrode metallic nitride layer 157, and a second electrode metal layer 158. The first electrode metallic nitride layer 155 functions as a diffusion barrier which prevents or reduces metal diffusion from the first electrode metal layer 156 into the doped semiconductor capacitor electrode layer 154 and into the upper node dielectric 153, which reduces the time-dependent dielectric breakdown (TDDB) of the capacitor 200C.

A masked or unmasked ion implantation process can be performed to form a deep source region 32 and a deep drain region 38. A heavily doped contact region 132 is also formed in the exposed portion of the lightly doped contact region 133 and the doped well portion of the lower electrode 128 in the capacitor region 200. The dielectric gate spacer 66, the gate electrode (52, 56, 57, 58), and the gate capping dielectric 59 may be employed as self-aligned etch mask structures during the masked ion implantation process. The combination of the source extension region 33 and the deep source region 32 constitutes a source region (32, 33). The combination of the drain extension region 37 and the deep drain region 38 constitutes a drain region (37, 38). A channel region 35 is located in the semiconductor substrate 8 between the source region (32, 33) and the drain region (37, 38).

A field effect transistor 100T is formed in the transistor region 100. The field effect transistor 100T is located on a first portion of the semiconductor substrate 8 and comprises a gate dielectric 51 including a first portion of a first dielectric material and a gate electrode (52, 56, 57, 58) comprising, from bottom to top, the doped semiconductor gate electrode 52 comprising a first portion of a gate semiconductor material, the first gate metal layer 56, the gate metallic nitride layer 57, and the second gate metal layer 58.

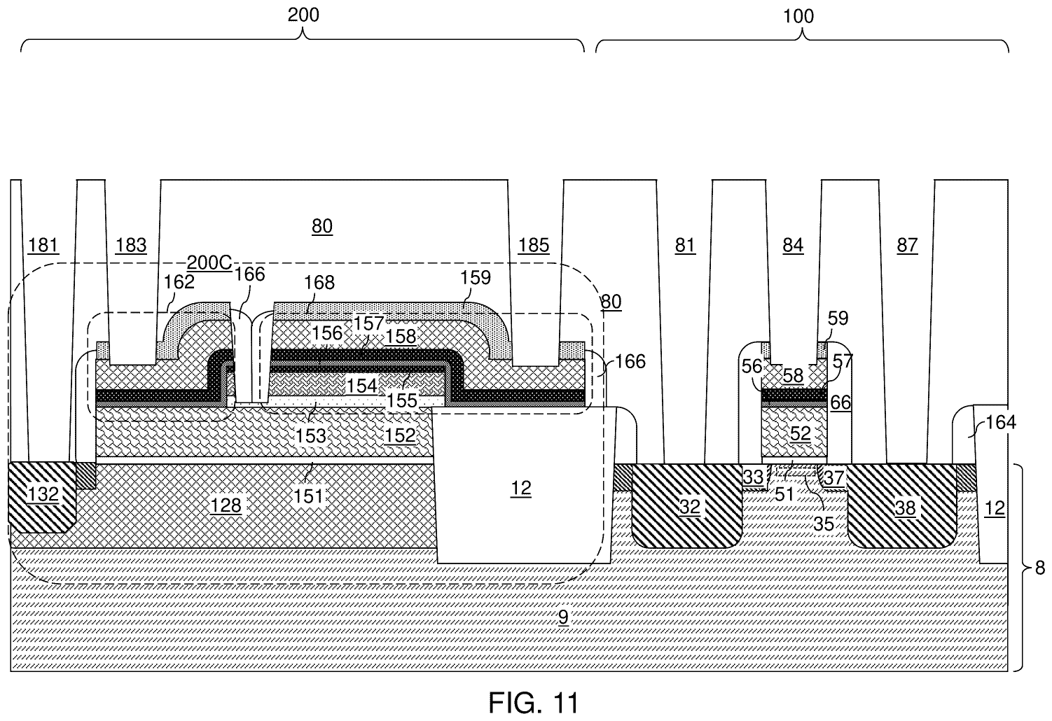

Referring to FIG. 11, a contact-level dielectric layer 80 can be formed over the field effect transistor 100T and the capacitor 200C. The top surface of the contact-level dielectric layer 80 may be planarized as needed, for example, by performing a chemical mechanical polishing process. Contact via cavities (81, 84, 87, 181, 183, 185) can be formed through the contact-level dielectric layer 80. The contact via cavities (81, 84, 87, 181, 183, 185) may comprise a source contact via cavity 81 that is formed on the deep source region 32, a gate contact via cavity 84 that is formed on the second gate metal layer 58 of the gate electrode (52, 56, 57, 58), a drain contact via cavity 87 that is formed on the deep drain region 38, a lower electrode contact via cavity 181 that is formed the lower electrode 128, a middle electrode contact via cavity 183 that is formed on the middle electrode contact structure 162, and an upper electrode contact via cavity 185 that is formed on the upper electrode 168.

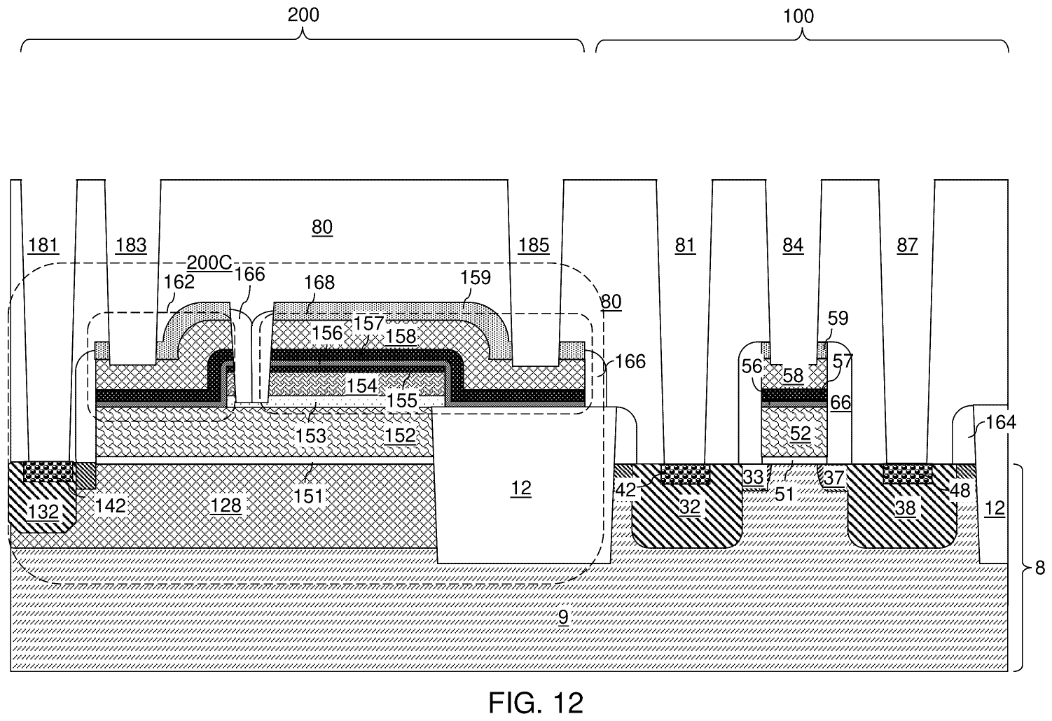

Referring to FIG. 12, various metal-semiconductor alloy (e.g., metal silicide) regions (42, 48, 142) can optionally be formed on physically exposed surfaces of semiconductor material portions, which include physically exposed surfaces of the deep source region 32, the deep drain region 38, and the heavily doped contact region 132 of the lower electrode 128. Generally, a metal layer that reacts with the semiconductor materials of the deep source region 32, the deep drain region 38, and the heavily doped contact region 132 of the lower electrode 128 can be deposited at the bottom of the contact via cavities (81, 84, 87, 181, 183, 185). The metal may comprise any silicide forming metal, such as Ti, Pd, Ni, Co, W, Ta, Mo, etc. An anneal process can be performed to induce formation of metal-semiconductor alloy (e.g., metal silicide) materials, such as Ti, Pd, Ni, Co, W, Ta or Mo silicide materials. Unreacted portions of the metal layer can be nitrided to suppress reaction with the forming gas of a subsequent TiN layer. The various metal-semiconductor alloy (e.g., metal silicide) regions (42, 48, 142) may comprise a source metal-semiconductor alloy region 42, a drain metal-semiconductor alloy region 48, an electrode metal-semiconductor alloy region 142. Alternatively, the metal-semiconductor alloy regions (42, 48, 142) may be omitted.

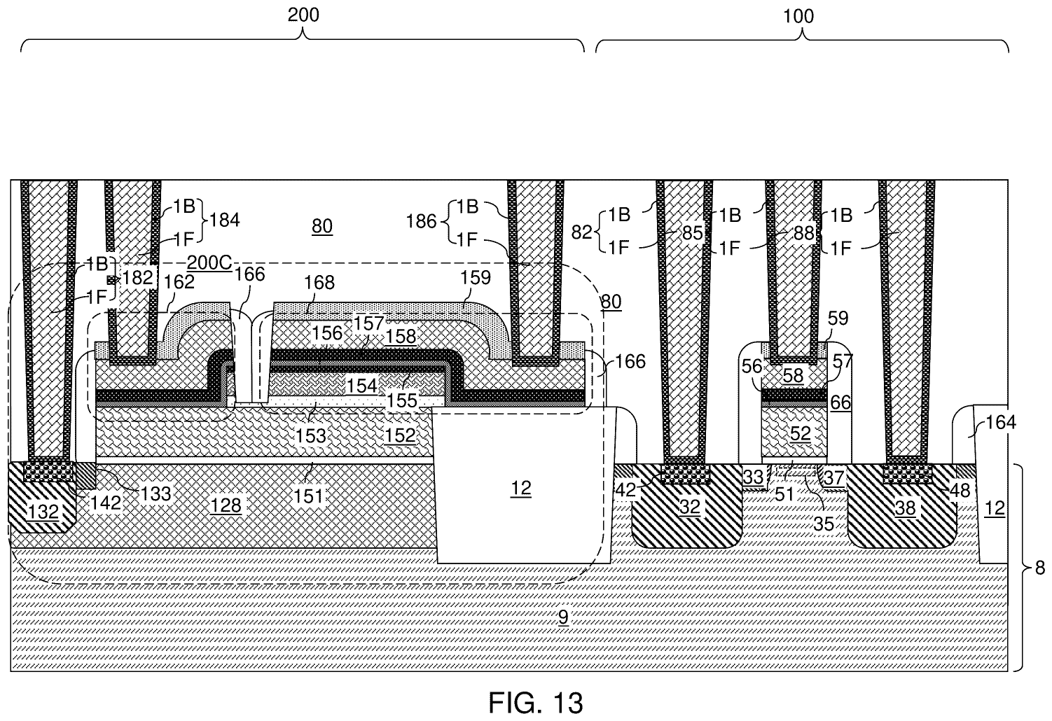

Referring to FIG. 13, various contact via structures (82, 85, 88, 182, 184, 186) can be formed in the contact via cavities (81, 84, 87, 181, 183, 185). For example, a source contact via structure 82 can be formed in the source contact via cavity 81, a gate contact via structure 85 can be formed in the gate contact via cavity 84, a drain contact via structure 88 can be formed in the drain contact via cavity 87, a lower electrode contact via structure 182 can be formed in the lower electrode contact via cavity 181, a middle electrode contact via structure 184 can be formed in the middle electrode contact via cavity 183, and an upper electrode contact via structure 186 can be formed in the upper electrode contact via cavity 185. Alternatively, the peripheral contact via structure 182 may be omitted if the substrate 8 (e.g., the lower electrode 128) is not externally biased in the completed device. Each of the contact via structures (82, 85, 88, 182, 184, 186) may comprise a respective combination of a metallic barrier liner 1B including a metallic barrier material (such as TiN, TaN, MON, and/or WN) and a metal fill material portion 1F including a metallic fill material (such as W, Ti, Ta, Mo, Ru, etc.).

Referring to all drawings and according to various embodiments of the present disclosure, a semiconductor structure comprises a field effect transistor 100T and a capacitor 200C located on a common substrate 8. The field effect transistor 100T is located on a first portion of the common substrate 8 and comprises a gate dielectric 51 including a first portion of a first dielectric material and a gate electrode (52, 56, 57, 58) comprising, from bottom to top, a doped semiconductor gate electrode 52 comprising a first portion of a gate semiconductor material, a first gate metal layer 56, and a second gate metal layer 58. The capacitor 200C comprises a middle electrode 152 including a second portion of the gate semiconductor material, an upper node dielectric 153, and an upper electrode 168 comprising, from bottom to top, a doped semiconductor capacitor electrode layer 154, a first electrode metallic nitride layer 155, a first electrode metal layer 156, and a second electrode metal layer 158.

In one embodiment, a top surface of the doped semiconductor gate electrode 52 contacts a bottom surface of the first gate metal layer 56. In one embodiment, the doped semiconductor capacitor electrode layer 154 contacts a bottom surface of the first electrode metallic nitride layer 155. In one embodiment, the first gate metal layer 56 and the first electrode metal layer 156 consist essentially of titanium and have a same thickness. In one embodiment, the second gate metal layer 58 and the second electrode metal layer 158 have a same material composition (e.g., tungsten) and have a same thickness.

In one embodiment, the gate electrode (52, 56, 57, 58) further comprises a gate metallic nitride layer 57 located between and contacting the first gate metal layer 56 and the second gate metal layer 58; and the upper electrode 168 further comprises second electrode metallic nitride layer 157 located between and contacting the first electrode metal layer 156 and the second electrode metal layer 158. In one embodiment, the gate metallic nitride layer 57 and the second electrode metallic nitride layer 157 have a same material composition (e.g., TiN) and a same thickness.

In one embodiment, the first electrode metallic nitride layer 155 consists essentially of titanium nitride, and the gate electrode does not have a metallic nitride layer located between the doped semiconductor gate electrode 52 and the first gate metal layer 56.

In one embodiment, the common substrate 8 comprises a semiconductor substrate, and a source region (32, 33), a drain region (37, 38), and channel regions 35 of the field effect transistor 100T are located in the semiconductor substrate 8. In one embodiment, a lower node dielectric 151 including a second portion of the first dielectric material is located between the middle electrode 152 and the common substrate 9.

In one embodiment, the middle electrode 152 has a greater lateral extent than the upper electrode of the capacitor 200C. In one embodiment, the upper node dielectric 153 and the middle electrode 152 have only a partial areal overlap in a plan view. Thus, the upper node dielectric 153 comprises a portion that does not have an areal overlap within the middle electrode 152, and the middle electrode 152 comprises a portion that does not have an areal overlap with the upper node dielectric 153. In one embodiment, the first electrode metal layer 156 and the second electrode metal layer 158 have a greater lateral extent than the first electrode metallic nitride layer 155.

In one embodiment, the semiconductor structure further comprises a lower electrode 128 embedded in an upper portion of the common substrate 8, and a lower node dielectric 151 including a second portion of the first dielectric material and located between the middle electrode 152 and the lower electrode 128.

In one embodiment, the semiconductor structure further comprises: a dielectric gate spacer 66 laterally surrounding the gate electrode (52, 56, 57, 58); and a dielectric capacitor spacer 166 laterally surrounding the upper electrode 168 and the middle electrode 152 and having a same material composition as the dielectric gate spacer 66.

In one embodiment, the semiconductor structure further comprises a shallow trench isolation structure 12 contacting a sidewall of the middle electrode 152, a segment of a bottom surface of the upper node dielectric 153, and an entirety of a bottommost surface of the first electrode metal layer 156 of the upper electrode 168.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising a field effect transistor and a capacitor located on common substrate, wherein:
the field effect transistor is located on a first portion of the common substrate, and comprises a gate dielectric including a first portion of a first dielectric material, and a gate electrode comprising, from bottom to top, a doped semiconductor gate electrode comprising a first portion of a gate semiconductor material, a first gate metal layer, and a second gate metal layer; and
the capacitor is located on second portion of the common substrate, and comprises a middle electrode including a second portion of the gate semiconductor material, an upper node dielectric, and an upper electrode comprising, from bottom to top, a doped semiconductor capacitor electrode layer, a first electrode metallic nitride layer, a first electrode metal layer, and a second electrode metal layer.

2. The semiconductor structure of claim 1, wherein a top surface of the doped semiconductor gate electrode contacts a bottom surface of the first gate metal layer.

3. The semiconductor structure of claim 2, wherein the doped semiconductor capacitor electrode layer contacts a bottom surface of the first electrode metallic nitride layer.

4. The semiconductor structure of claim 3, wherein the first gate metal layer and the first electrode metal layer consist essentially of titanium and have a same thickness.

5. The semiconductor structure of claim 3, wherein the second gate metal layer and the second electrode metal layer have a same material composition and have a same thickness.

6. The semiconductor structure of claim 3, wherein:
the gate electrode further comprises a gate metallic nitride layer located between and contacting the first gate metal layer and the second gate metal layer;
the upper electrode further comprises a second electrode metallic nitride layer located between and contacting the first electrode metal layer and the second electrode metal layer; and
the gate metallic nitride layer and the second electrode metallic nitride layer have a same material composition and a same thickness.

7. The semiconductor structure of claim 2, wherein the first electrode metallic nitride layer consists essentially of titanium nitride, and the gate electrode does not have a metallic nitride layer located between the doped semiconductor gate electrode and the first gate metal layer.

8. The semiconductor structure of claim 1, wherein the common substrate comprises a semiconductor substrate, and a source region, a drain region, and a channel region of the field effect transistor are located in the semiconductor substrate.

9. The semiconductor structure of claim 1, wherein the middle electrode has a greater lateral extent than the upper electrode.

10. The semiconductor structure of claim 9, wherein the first electrode metal layer and the second electrode metal layer have a greater lateral extent than the first electrode metallic nitride layer.

11. The semiconductor structure of claim 1, further comprising:
a lower electrode embedded in an upper portion of the common substrate; and
a lower node dielectric including a second portion of the first dielectric material located between the middle electrode and the lower electrode.

12. The semiconductor structure of claim 1, further comprising:
a dielectric gate spacer laterally surrounding the gate electrode;
a dielectric capacitor spacer laterally surrounding the upper electrode and the middle electrode and having a same material composition as the dielectric gate spacer.

13. The semiconductor structure of claim 1, further comprising a shallow trench isolation structure contacting a sidewall of the middle electrode, a segment of a bottom surface of the upper node dielectric, and an entirety of a bottommost surface of the first electrode metal layer of the upper electrode.

14. The semiconductor structure of claim 1, wherein the doped semiconductor gate electrode and the middle electrode have a same height and a same material composition.

15. A method of forming a semiconductor structure, comprising:
forming a gate dielectric material layer, a first doped semiconductor material layer, and a capacitor material layer stack over a substrate, wherein the capacitor material layer stack comprises, from bottom to top, an upper node dielectric material layer, a second doped semiconductor material layer, and a first electrode metallic nitride material layer;
removing a first portion of the capacitor material layer stack from a transistor region while retaining at least a part of a second portion of the capacitor material layer stack in a capacitor region;
forming an upper layer stack including a first metal layer and a second metal layer over the second portion of the capacitor material layer stack in the capacitor region and over the first doped semiconductor material layer in the transistor region; and
patterning the upper layer stack, the second portion of the capacitor material layer stack and first doped semiconductor material layer to form a capacitor in the capacitor region and to form a gate electrode in the transistor region.

16. The method of claim 15, wherein:
a patterned portion of the first doped semiconductor material layer in the capacitor region comprises a middle electrode of the capacitor;
patterned portions of the second doped semiconductor material layer, the first electrode metallic nitride material layer, and the upper layer stack in the capacitor region comprise an upper electrode of the capacitor; and
a patterned portion of the upper node dielectric material layer in the capacitor region comprises an upper node dielectric located between the middle electrode and the upper electrode.

17. The method of claim 16, wherein a contiguous combination of patterned portions of the upper layer stack and the first doped semiconductor material layer in the transistor region comprise the gate electrode.

18. The method of claim 17, further comprising conformally depositing and anisotropically etching a dielectric spacer material layer to form:
a dielectric gate spacer laterally surrounding the gate electrode; and
a dielectric capacitor spacer laterally surrounding the upper electrode and the middle electrode and contacting a sidewall of a shallow trench isolation structure.

19. The method of claim 18, further comprising patterning the gate dielectric material layer during the step of anisotropically etching the dielectric spacer material layer to form a gate dielectric between the substrate and the gate electrode in the transistor region, and to form a lower node dielectric between the substrate and the middle electrode in the capacitor region.

20. The method of claim 16, wherein:
the upper layer stack further comprises a second electrode metallic nitride material layer located between the first metal layer and the second metal layer; and
the first metal layer is deposited directly on a top surface of the first portion of the first doped semiconductor material layer in the transistor region.
